(19) United States
(12) Patent Application Publication
(10) Pub. No.: US 2026/0305375 A1
(43) Pub. Date: Oct. 1, 2026

(54) ELECTRONIC PACKAGE, MANUFACTURING METHOD THEREOF, ELECTRONIC COMPONENT, AND MANUFACTURING METHOD THEREOF

(71) Applicant: SILICONWARE PRECISION INDUSTRIES CO., LTD., Taichung City (TW)

(72) Inventors: Ying-Chi CHI, Taichung City (TW); Hsuan-Jen WANG, Taichung City (TW); Hao-Cheng WANG, Taichung City (TW); Yi-Chun LAI, Taichung City (TW); Hung-Hsiang FANG, Taichung City (TW)

(73) Assignee: SILICONWARE PRECISION INDUSTRIES CO., LTD., Taichung City (TW)

(21) Appl. No.: 19/423,727

(22) Filed: Dec. 17, 2025

(30) Foreign Application Priority Data
Mar. 31, 2025 (TW) 114112386

(51) Int. Cl. H10W 70/00; H10W 70/02; H10W 72/00; H10W 74/10

(52) U.S. Cl. CPC H10W 70/099; H10W 70/02; H10W 72/823; H10W 74/111

(57) ABSTRACT

An electronic component of an electronic package is made by forming a multi-layer structure as insulation module on a first side of an interposer to improve the rigidity and mechanical strength of the electronic component, and therefore a warping problem of the electronic component in the electronic package during the thermal process can be avoided.

### BACKGROUND

### 1. Technical Field

The present disclosure relates to a semiconductor packaging technology, and more particularly, to an electronic package and manufacturing method thereof and an electronic component and manufacturing method thereof that can reduce costs.

### 2. Description of Related Art

With the vigorous development of the electronics industry, developments of various related products are also moving towards high density, high performance, and light, thin, short and small. To this purpose, the industry has developed various integrated multi-functional advanced packaging forms to meet the requirements of electronic products being light. Thin, short, small and high density.

In addition to the continuous development of advanced processes, semiconductor industries are also looking for ways to keep the chip maintain small volume while maintaining high performance, the concept of “heterogeneous integration” has become a contemporary popular concept, the chip has also shifted from the original single-layer packaging to multi-layer 3D stacked advanced packaging.

FIG. 1 is a schematic cross-sectional view showing a conventional through-silicon interposer (TSI). As shown in FIG. 1, the through-silicon interposer 1 is manufactured by disposing a silicon board 11 on a glass plate 9, the silicon board 11 has a first side 11a and a second side 11b opposite to the first side 11a, and the silicon board 11 is disposed with its second side 11b on the glass plate 9. A plurality of conductive through-silicon vias (TSV) 110 passing through the first side 11a and the second side 11b are formed in the silicon board 11, and the conductive through-silicon vias 110 protrude from the first side 11a of the silicon board 11 to serve as protruded portions 110a. Then, an insulating layer 12 is formed on the first side 11a of the silicon board 11 and covers side surfaces 110c of the protruded portions 110a, and the insulating layer 12 is a single polyimide (PI) layer. Afterwards, conductive bumps 112 and solder materials 113 are formed on top surfaces of the protruded portions 110a by electroplating a conductive layer 111.

In subsequent applications, such as the packaging operation of a fan-out embedded bridge (FOEB), the glass plate 9 is first removed, and then the through-silicon interposer 1 is embedded in a molding compound as an electrical bridging element and is electrically connected to the circuit structure on the molding compound. Therefore, a plurality of semiconductor chips on the circuit structure can be electrically bridged to the solder materials 113 on the protruded portions 110a of the conductive through-silicon vias 110 of the through-silicon interposer 1 through the circuit structure.

However, in the conventional manufacturing method of the through-silicon interposer 1, the single PI layer used as the insulating layer 12 leads to poor rigidity and mechanical strength of the through-silicon interposer 1, thereby in the subsequent applications of thermal process (e.g., the process of embedding the through-silicon interposer 1 in the molding compound), the through-silicon interposer 1 is prone to warp (as shown by a dotted line L in FIG. 1, which shows the warping shape of the through-silicon interposer 1). The alignment deviation of the electrical connection between the circuit structure and the protruded portions 110a is thus occurred, electrical connection between both the circuit structure and the protruded portions 110a is ineffectively, resulting in poor reliability of the overall electrical connection, and thus it is difficult to improve the yield of the electronic package.

Therefore, there is an urgent to overcome the aforementioned problems of conventional techniques.

### SUMMARY

In view of the aforementioned shortcomings of the prior art, the present disclosure provides an electronic component, including: an interposer having a first side and a second side opposite to the first side, and a plurality of conductors are formed in the interposer and protruded from the first side of the interposer to serve as conductive protrusions; and an insulation module formed on the first side of the interposer and covering a side surface of the conductive protrusions. The insulation module is a multi-layer structure including a passivation layer and an insulating layer, the passivation layer includes a silicon nitride material, and the insulating layer includes a titanium nitride material.

The present disclosure further provides a manufacturing method of an electronic component, including: providing an interposer having a first side and a second side opposite to the first side, and a plurality of conductors are formed in the interposer and protruded from the first side of the interposer to serve as conductive protrusions; and forming an insulation module on the first side of the interposer, and the insulation module covering the side surface of the conductive protrusions, wherein the insulation module is a multi-layer structure including a passivation layer and an insulating layer, the passivation layer includes a silicon nitride material, and the insulating layer includes a titanium nitride material.

In the aforementioned electronic component and the manufacturing method thereof, the passivation layer covers the side surface of the conductive protrusions.

In the aforementioned electronic component and the manufacturing method thereof, the insulating layer is formed between any two of the plurality of conductors.

In the aforementioned electronic component and the manufacturing method thereof, the insulating layer does not directly contact each of the conductors.

In the aforementioned electronic component and the manufacturing method thereof, further including a conductive bump formed on the conductive protrusions. For example, a conductive layer is formed between the conductive protrusions and the conductive bump, and the conductive layer includes a titanium-copper alloy material.

The present disclosure further provides an electronic package, including: an encapsulation layer; the aforementioned electronic component serving as an electrical bridging element and embedded in the encapsulation layer; a circuit structure disposed on the encapsulation layer and electrically connected to the conductive protrusions of the electronic component; and a functional element disposed on the circuit structure and electrically connected to the circuit structure, and the functional element electrically bridged to the electronic component through the circuit structure.

The present disclosure further provides a manufacturing method of an electronic package, including: embedding the aforementioned electronic component served as an electrical bridging element in the encapsulation layer, forming a circuit structure on the encapsulation layer, and the circuit structure electrically connected to the conductive protrusions of the electronic component; and disposing a functional element on the circuit structure, the functional element electrically connected to the circuit structure, and the functional element electrically bridged to the electronic component through the circuit structure.

In the aforementioned electronic component and the manufacturing method thereof, further including embedding a plurality of conductive pillars in the encapsulation layer, and the plurality of conductive pillars electrically connected to the circuit structure.

In the aforementioned electronic component and the manufacturing method thereof, further including forming a wiring structure on the second side of the interposer, and the wiring structure electrically connected to the conductors. Further, it can include forming a plurality of conductive components on the wiring structure.

It can be seen from the above that, in the electronic package, the manufacturing method thereof, the electronic component and the manufacturing method thereof of the present disclosure, the conventional single PI layer is replaced with a multi-layer structure such as the passivation layer (silicon nitride material) and the insulating layer (titanium nitride material) to improve the rigidity and mechanical strength of the electronic component. Thus, compared to the prior art, the warping problem of the electronic component in the electronic package of the present disclosure during the thermal process can be avoided, the reliability of the electrical connection between the circuit structure and the electronic component can be improved, thereby the yield of the electronic package can be effectively enhanced.

### BRIEF DESCRIPTION OF THE DRAWINGS

FIG. 1 is a schematic cross-sectional view showing a conventional through-silicon interposer.

FIG. 2A to FIG. 2E are schematic cross-sectional views showing a manufacturing method of an electronic component of the present disclosure.

FIG. 3 is a schematic cross-sectional view showing an electronic package of the present disclosure.

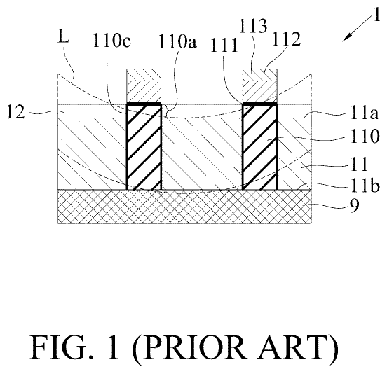

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “a,” and the like are merely used for clear explanation rather than limiting the practicable scope of the present disclosure, and thus, alterations or adjustments of the relative relationships thereof without essentially altering the technical contents should still be considered in the practicable scope of the present disclosure.

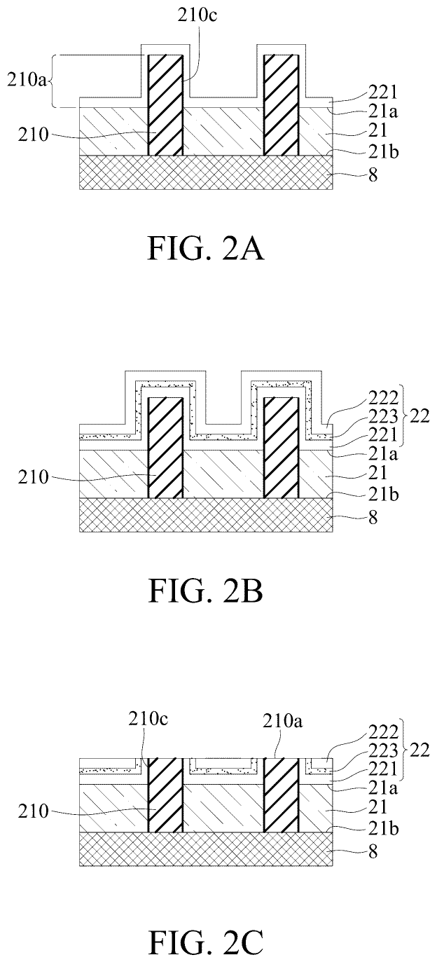

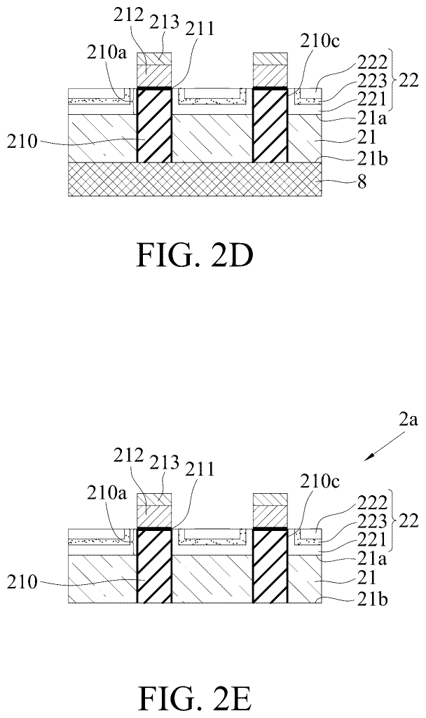

FIG. 2A to FIG. 2E are schematic cross-sectional views showing a manufacturing method of an electronic component 2a of the present disclosure.

As shown in FIG. 2A, providing an interposer 21 with a first side 21a and a second side 21b opposite to the first side 21a, a plurality of conductors 210 penetrating (or conducting) the first side 21a and the second side 21b are formed in the interposer 21, and the conductors 210 protrude from the first side 21a of the interposer 21 to serve as conductive protrusions 210a. Then, a first passivation layer 221 covering an upper surface of the interposer 21 and encapsulating the conductive protrusions 210a of the conductors 210 is formed on the first side 21a of the interposer 21.

In one embodiment, the interposer 21 is a semiconductor plate such as silicon or glass, etc., the conductors 210 are metals such as copper, and the conductors 210 become through-silicon via (TSV). For example, a partial material of the interposer 21 on the first side 21a is removed by etching, and the conductors 210 protrude from the first side 21a of the interposer 21.

Besides, the interposer 21 is disposed on a temporary carrier 8 with its second side 21b. For example, the temporary carrier 8 is a glass plate.

In addition, the first passivation layer 221 is a silicon nitride (Si₃N₄) layer or a silicon oxide layer. For example, the first passivation layer 221 is formed by physical vapor deposition (PVD).

As shown in FIG. 2B, an insulating layer 223 is formed on the first passivation layer 221, and a second passivation layer 222 is formed on the insulating layer 223, such that the first passivation layer 221, the insulating layer 22 and the second passivation layer 222 are served as an insulation module 22.

In one embodiment, the insulating layer 223 is a titanium nitride (TiN) layer, and the second passivation layer 222 is a silicon nitride (Si₃N₄) layer or a silicon oxide layer. For example, the second passivation layer 222 is formed by physical vapor deposition (PVD). It should be understood that the first passivation layer 221 and the second passivation layer 222 can be the same or different materials, but the insulation module 22 must include silicon nitride (Si₃N₄).

As shown in FIG. 2C, a flattening process is performed, such that end surfaces of the conductive protrusions 210a of the conductors 210 and surfaces of the insulation module 22 (a surface of the first passivation layer 221, a surface of the insulating layer 223 and a surface of the second passivation layer 222) are flush with each other, the end surfaces of the conductive protrusions 210a of the conductors 210 are thus exposed from the insulation module 22, and the first passivation layer 221 covers side surfaces 210c of the conductive protrusions 210a of the conductors 210.

In one embodiment, a partial material of the conductive protrusions 210a of the conductors 210, a partial material of the first passivation layer 221, a partial material of the insulating layer 223 and a partial material of the second passivation layer 222 are removed by grinding, and the end surfaces of the conductive protrusions 210a of the conductors 210, the surface of the first passivation layer 221, the surface of the insulating layer 223 and the surface of the second passivation layer 222 are flush with each other.

Furthermore, the insulating layer 223 is formed between each of the conductors 210, and the insulating layer 223 does not directly contact each of the conductors 210.

As shown in FIG. 2D, a plurality of conductive bumps 212 electrically connected to the conductive protrusions 210a are formed by electroplating on the first side 21a of the interposer 21 through a conductive layer 211.

In one embodiment, the conductive layer 211 is a titanium-copper (TiCu) alloy layer. The first side 21a of the interposer 21 can first be covered by the conductive layer 211, a patterned photoresist (not shown) is subsequently formed on the conductive layer 211 to form the plurality of conductive bumps 212 in the patterned photoresist, and the patterned photoresist and the conductive layer 211 thereunder are removed. For example, the conductive bumps 212 are copper pillars, and a solder material 213 can be formed on the conductive bump 212 as required.

As shown in FIG. 2E, the temporary carrier 8 is removed, and a singulation process is performed to obtain a plurality of electronic components 2a.

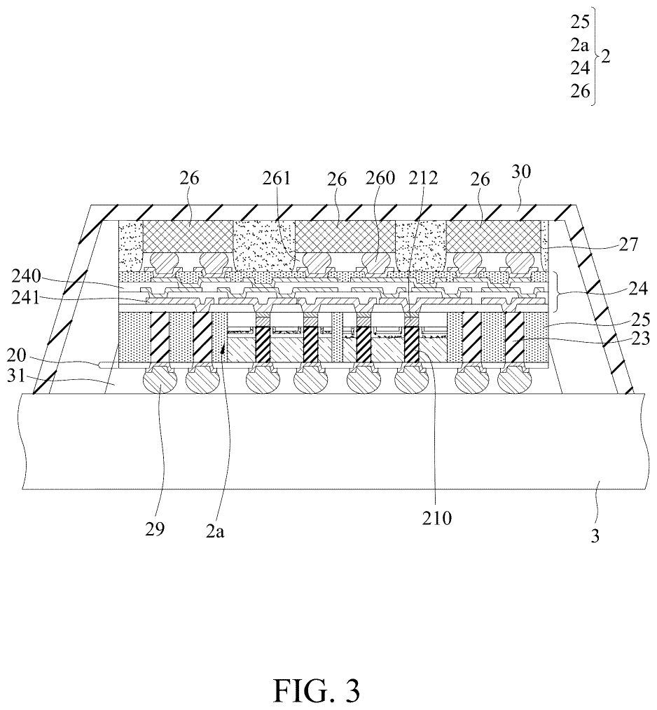

In one embodiment, the electronic component 2a can be used as an electrical bridging element (bridge die) to be disposed in an electronic package 2 as shown in FIG. 3. For example, the electronic package 2 includes an encapsulation layer 25, at least one electronic component 2a embedded in the encapsulation layer 25, at least one conductive pillar 23 embedded in the encapsulation layer 25, a circuit structure 24 disposed on an upper side of the encapsulation layer 25 and electrically connected to the electronic component 2a, at least one functional element 26 disposed on and electrically connected to the circuit structure 24, and a packaging layer 27 covering the functional element 26.

The circuit structure 24 includes at least one dielectric layer 240 and a circuit layer 241 disposed on the dielectric layer 240 and electrically connected to the conductive protrusions 210a (may through conductive bumps 212 or the solder material 213) in such as the redistribution layer (RDL) specification. For example, the material forming the circuit layer 241 is copper, and the material forming the dielectric layer 240 is such as polybenzoxazole (PBO), polyimide (PI), prepreg (PP), or other dielectric materials.

The conductive pillar 23 is electrically connected to the circuit structure 24 and made of a metal such as copper or solder material, but is not limited to the above.

The encapsulation layer 25 is an insulating material, such as polyimide (PI), dry film, molding colloid such as epoxy resin or molding compound. For example, the encapsulation layer 25 can be formed by liquid compound, injection, lamination, or compression molding.

The functional element 26 is, for example, an active element, a passive element, a packaging structure, or a combination thereof, such that a plurality of the functional elements 26 are electrically bridged to each other through the circuit structure 24 and the electronic component 2a. The active element is, for example, a semiconductor chip, and the passive element is, for example, a resistor, a capacitor and an inductor.

In one embodiment, the functional element 26 is a semiconductor chip, which can be disposed on the circuit structure 24 in a flip-chip manner and electrically connected to the circuit layer 241 through a plurality of conductive bumps 260 such as solder bumps, copper bumps, or other bumps, and the conductive bumps 260 are covered by an underfill 261; alternatively, the functional element 26 can be electrically connected to the circuit layer 241 by means of bonding through a plurality of welding wires; or the functional element 26 can directly contact the circuit layer 241. It should be understood that there are various ways to electrically connect the functional element 26 to the circuit structure 24, but is not limited to the above.

The packaging layer 27 is an insulating material, such as polyimide (PI), dry film, molding colloid such as epoxy or molding compound. For example, the packaging layer 27 can be formed on the circuit structure 24 by liquid encapsulant, injection, lamination, or compression molding. It should be understood that materials of the packaging layer 27 and the encapsulation layer 25 can be the same or different.

Besides, a wiring structure 20 electrically connecting the conductive pillar and the conductors 210 can be formed on a lower side of the encapsulation layer 25 and the second side 21b of the interposer 21, and a plurality of conductive components 29 such as solder balls can be combined on the wiring structure 20.

In one embodiment, the electronic package 2 can be placed on an electronic device 3 such as a circuit board through conductive components 29, and the conductive components 29 are covered by a underfill 31. For example, a heat sink 30 can be disposed on the electronic device 3 covering the electronic package 2 to dissipate heat from the electronic package 2.

Therefore, the manufacturing method of the electronic component 2a of the present disclosure mainly adopts a multi-layer structure design of the insulation module 22, which includes the first passivation layer 221 and the second passivation layer 222 (silicon nitride material) and the insulating layer 223 (titanium nitride material) and other different materials to improve the rigidity and mechanical strength of the electronic component 2a. Thus, compared with the single PI layer of the prior art, the warping problem of warping of the electronic component 2a in the electronic package 2 of the present disclosure during the thermal process (such as the process of forming the encapsulation layer 25) can be avoided, the reliability of the electrical connection between the circuit structure 24 and the electronic component 2a can be improved, thereby the yield of the electronic package 2 can be effectively enhanced.

The present disclosure provides the electronic component 2a including: the interposer 21 and the insulation module 22.

The interposer 21 has the first side 21a and the second side 21b opposite to the first side 21a, the plurality of conductors 210 are formed in the interposer 21, and the conductors 210 are protruded from the first side 21a of the interposer 21 to serve as the conductive protrusions 210a.

The insulation module 22 is formed on the first side 21a of the interposer 21 and covers the side surfaces 210c of the conductive protrusions 210a. The insulation module 22 includes the first passivation layer 221, the second passivation layer 222 and the insulating layer 223, the first passivation layer 221 and the second passivation layer 222 are silicon nitride layers, and the insulating layer 223 includes titanium nitride material.

In one embodiment, the first passivation layer 221 covers the side surfaces 210c of the conductive protrusions 210a.

In one embodiment, the insulating layer 223 is formed between any two of the plurality of conductors 210.

In one embodiment, the insulating layer 223 does not directly contact each of the conductors 210.

In one embodiment, the electronic component 2a further includes the conductive bumps 212 formed on the conductive protrusions 210a. Further, the conductive layer 211 is formed between the conductive protrusions 210the and the conductive bumps 212, and the conductive layer 211 includes the titanium-copper alloy material.

The present disclosure also provides the electronic package 2 including: the encapsulation layer 25, at least one electronic component 2a, the circuit structure 24 and at least one functional element 26.

The electronic component 2a serves as the electrical bridging element, which is embedded in the encapsulation layer 25.

The circuit structure 24 is disposed on the encapsulation layer 25 and electrically connected to the conductive protrusions 210a on the first side 21a of the interposer 21.

The functional element 26 is disposed on the circuit structure 24 and electrically connected to the circuit structure 24, such that the functional element 26 is electrically bridged to the electronic component 2a through the circuit structure 24.

In one embodiment, a plurality of conductive pillars 23 electrically connected to the circuit structure 24 are embedded in the encapsulation layer 25.

In one embodiment, the electronic package 2 further includes the wiring structure 20 electrically connected to the conductors 210 formed on the second side 21b of the interposer 21. Furthermore, the electronic package 2 may include the plurality of conductive components 29 formed on the wiring structure 20.

To sum up, in the electronic package, the manufacturing method thereof, the electronic component and the manufacturing method thereof of the present disclosure, the conventional single PI layer is replaced with a multi-layer structure including a first passivation layer and a second passivation layer (silicon nitride material) and the insulating layer (titanium nitride material) to improve the rigidity and mechanical strength of the electronic component. Thus, the warping problem of the electronic component in the electronic package of the present disclosure during the thermal process can be avoided, the reliability of the electrical connection between the circuit structure and the electronic component can be improved, thereby the yield of the electronic package can be effectively enhanced.

The above embodiments are disposed for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic component, comprising:
an interposer having a first side and a second side opposite to the first side, and a plurality of conductors formed in the interposer and protruded from the first side of the interposer to serve as conductive protrusions; and
an insulation module being a multi-layer structure comprising a passivation layer and an insulating layer, which being formed on the first side of the interposer and covering a side surface of the conductive protrusions.

2. The electronic component of claim 1, wherein the passivation layer comprises a silicon nitride material, and the insulating layer comprises a titanium nitride material.

3. The electronic component of claim 1, wherein the passivation layer covers the side surface of the conductive protrusions.

4. The electronic component of claim 1, wherein the insulating layer is formed between any two of the plurality of conductors.

5. The electronic component of claim 1, wherein the insulating layer does not directly contact each of the conductors.

6. The electronic component of claim 1, further comprising a conductive bump formed on the conductive protrusions.

7. The electronic component of claim 6, wherein a conductive layer is formed between the conductive protrusions and the conductive bump, and the conductive layer comprises a titanium-copper alloy material.

8. An electronic package, comprising:
an encapsulation layer;
the electronic component according to claim 1 serving as an electrical bridging element and embedded in the encapsulation layer;
a circuit structure disposed on the encapsulation layer and electrically connected to the conductive protrusions of the electronic component; and
a functional element disposed on the circuit structure and electrically connected to the circuit structure, and the functional element electrically bridged to the electronic component through the circuit structure.

9. The electronic package of claim 8, further comprising a plurality of conductive pillars embedded in the encapsulation layer and electrically connected to the circuit structure.

10. The electronic package of claim 8, further comprising a wiring structure formed on the second side of the interposer and electrically connected to the conductors.

11. The electronic package of claim 10, further comprising a plurality of conductive components formed on the wiring structure.

12. An electronic package, comprising:
an encapsulation layer;
the electronic component according to claim 2 serving as an electrical bridging element and embedded in the encapsulation layer;
a circuit structure disposed on the encapsulation layer and electrically connected to the conductive protrusions of the electronic component; and
a functional element disposed on the circuit structure and electrically connected to the circuit structure, and the functional element electrically bridged to the electronic component through the circuit structure.

13. The electronic package of claim 12, further comprising a plurality of conductive pillars embedded in the encapsulation layer and electrically connected to the circuit structure.

14. The electronic package of claim 12, further comprising a wiring structure formed on the second side of the interposer and electrically connected to the conductors.

15. The electronic package of claim 14, further comprising a plurality of conductive components formed on the wiring structure.

16. An electronic package, comprising:
an encapsulation layer;
the electronic component according to claim 3 serving as an electrical bridging element and embedded in the encapsulation layer;
a circuit structure disposed on the encapsulation layer and electrically connected to the conductive protrusions of the electronic component; and
a functional element disposed on the circuit structure and electrically connected to the circuit structure, and the functional element electrically bridged to the electronic component through the circuit structure.

17. The electronic package of claim 16, further comprising a plurality of conductive pillars embedded in the encapsulation layer and electrically connected to the circuit structure.

18. The electronic package of claim 16, further comprising a wiring structure formed on the second side of the interposer and electrically connected to the conductors.

19. The electronic package of claim 18, further comprising a plurality of conductive components formed on the wiring structure.

20. An electronic package, comprising:
an encapsulation layer;
the electronic component according to claim 4 serving as an electrical bridging element and embedded in the encapsulation layer;
a circuit structure disposed on the encapsulation layer and electrically connected to the conductive protrusions of the electronic component; and
a functional element disposed on the circuit structure and electrically connected to the circuit structure, and the functional element electrically bridged to the electronic component through the circuit structure.

21. The electronic package of claim 20, further comprising a plurality of conductive pillars embedded in the encapsulation layer and electrically connected to the circuit structure.

22. The electronic package of claim 20, further comprising a wiring structure formed on the second side of the interposer and electrically connected to the conductors.

23. The electronic package of claim 22, further comprising a plurality of conductive components formed on the wiring structure.

24. An electronic package, comprising:
an encapsulation layer;
the electronic component according to claim 5 serving as an electrical bridging element and embedded in the encapsulation layer;
a circuit structure disposed on the encapsulation layer and electrically connected to the conductive protrusions of the electronic component; and
a functional element disposed on the circuit structure and electrically connected to the circuit structure, and the functional element electrically bridged to the electronic component through the circuit structure.

25. The electronic package of claim 24, further comprising a plurality of conductive pillars embedded in the encapsulation layer and electrically connected to the circuit structure.

26. The electronic package of claim 24, further comprising a wiring structure formed on the second side of the interposer and electrically connected to the conductors.

27. The electronic package of claim 26, further comprising a plurality of conductive components formed on the wiring structure.

28. An electronic package, comprising:
an encapsulation layer;
the electronic component according to claim 6 serving as an electrical bridging element and embedded in the encapsulation layer;
a circuit structure disposed on the encapsulation layer and electrically connected to the conductive protrusions of the electronic component; and
a functional element disposed on the circuit structure and electrically connected to the circuit structure, and the functional element electrically bridged to the electronic component through the circuit structure.

29. The electronic package of claim 28, further comprising a plurality of conductive pillars embedded in the encapsulation layer and electrically connected to the circuit structure.

30. The electronic package of claim 28, further comprising a wiring structure formed on the second side of the interposer and electrically connected to the conductors.

31. The electronic package of claim 30, further comprising a plurality of conductive components formed on the wiring structure.

32. An electronic package, comprising:
an encapsulation layer;
the electronic component according to claim 7 serving as an electrical bridging element and embedded in the encapsulation layer;
a circuit structure disposed on the encapsulation layer and electrically connected to the conductive protrusions of the electronic component; and
a functional element disposed on the circuit structure and electrically connected to the circuit structure, and the functional element electrically bridged to the electronic component through the circuit structure.

33. The electronic package of claim 32, further comprising a plurality of conductive pillars embedded in the encapsulation layer and electrically connected to the circuit structure.

34. The electronic package of claim 32, further comprising a wiring structure formed on the second side of the interposer and electrically connected to the conductors.

35. The electronic package of claim 34, further comprising a plurality of conductive components formed on the wiring structure.

36. A method for manufacturing an electronic component, comprising:
providing an interposer having a first side and a second side opposite to the first side, and a plurality of conductors formed in the interposer and protruded from the first side of the interposer to serve as conductive protrusions; and
forming an insulation module on the first side of the interposer, and the insulation module covering a side surface of the conductive protrusions, wherein the insulation module is a multi-layer structure comprising a passivation layer and an insulating layer.

37. The method for manufacturing the electronic component of claim 36, wherein the passivation layer comprises a silicon nitride material, and the insulating layer comprises a titanium nitride material.

38. The method for manufacturing the electronic component of claim 36, wherein the passivation layer covers the side surface of the conductive protrusions.

39. The method for manufacturing the electronic component of claim 36, wherein the insulating layer is formed between any two of the plurality of conductors.

40. The method for manufacturing the electronic component of claim 36, wherein the insulating layer does not directly contact each of the conductors.

41. The method for manufacturing the electronic component of claim 36, further comprising a conductive bump formed on the conductive protrusions.

42. The method for manufacturing the electronic component of claim 41, wherein a conductive layer is formed between the conductive protrusions and the conductive bump, and the conductive layer comprises a titanium-copper alloy material.

43. A method for manufacturing an electronic package, comprising:
embedding the electronic component according to claim 1 served as an electrical bridging element in an encapsulation layer;
forming a circuit structure on the encapsulation layer, and the circuit structure electrically connected to the conductive protrusions of the electronic component; and
disposing a functional element on the circuit structure, the functional element electrically connected to the circuit structure, and the functional element electrically bridged to the electronic component through the circuit structure.

44. The method for manufacturing the electronic package of claim 43, further comprising embedding a plurality of conductive pillars in the encapsulation layer, and the plurality of conductive pillars electrically connected to the circuit structure.

45. The method for manufacturing the electronic package of claim 43, further comprising forming a wiring structure on the second side of the interposer, and the wiring structure electrically connected to the conductors.

46. The method for manufacturing the electronic package of claim 45, further comprising forming a plurality of conductive components on the wiring structure.

47. A method for manufacturing an electronic package, comprising:
embedding the electronic component according to claim 2 served as an electrical bridging element in an encapsulation layer;
forming a circuit structure on the encapsulation layer, and the circuit structure electrically connected to the conductive protrusions of the electronic component; and
disposing a functional element on the circuit structure, the functional element electrically connected to the circuit structure, and the functional element electrically bridged to the electronic component through the circuit structure.

48. The method for manufacturing the electronic package of claim 47, further comprising embedding a plurality of conductive pillars in the encapsulation layer, and the plurality of conductive pillars electrically connected to the circuit structure.

49. The method for manufacturing the electronic package of claim 47, further comprising forming a wiring structure on the second side of the interposer, and the wiring structure electrically connected to the conductors.

50. The method for manufacturing the electronic package of claim 49, further comprising forming a plurality of conductive components on the wiring structure.

51. A method for manufacturing an electronic package, comprising:
embedding the electronic component according to claim 3 served as an electrical bridging element in an encapsulation layer;
forming a circuit structure on the encapsulation layer, and the circuit structure electrically connected to the conductive protrusions of the electronic component; and
disposing a functional element on the circuit structure, the functional element electrically connected to the circuit structure, and the functional element electrically bridged to the electronic component through the circuit structure.

52. The method for manufacturing the electronic package of claim 51, further comprising embedding a plurality of conductive pillars in the encapsulation layer, and the plurality of conductive pillars electrically connected to the circuit structure.

53. The method for manufacturing the electronic package of claim 51, further comprising forming a wiring structure on the second side of the interposer, and the wiring structure electrically connected to the conductors.

54. The method for manufacturing the electronic package of claim 53, further comprising forming a plurality of conductive components on the wiring structure.

55. A method for manufacturing an electronic package, comprising:
embedding the electronic component according to claim 4 served as an electrical bridging element in an encapsulation layer;
forming a circuit structure on the encapsulation layer, and the circuit structure electrically connected to the conductive protrusions of the electronic component; and
disposing a functional element on the circuit structure, the functional element electrically connected to the circuit structure, and the functional element electrically bridged to the electronic component through the circuit structure.

56. The method for manufacturing the electronic package of claim 55, further comprising embedding a plurality of conductive pillars in the encapsulation layer, and the plurality of conductive pillars electrically connected to the circuit structure.

57. The method for manufacturing the electronic package of claim 55, further comprising forming a wiring structure on the second side of the interposer, and the wiring structure electrically connected to the conductors.

58. The method for manufacturing the electronic package of claim 57, further comprising forming a plurality of conductive components on the wiring structure.

59. A method for manufacturing an electronic package, comprising:
embedding the electronic component according to claim 5 served as an electrical bridging element in an encapsulation layer;
forming a circuit structure on the encapsulation layer, and the circuit structure electrically connected to the conductive protrusions of the electronic component; and
disposing a functional element on the circuit structure, the functional element electrically connected to the circuit structure, and the functional element electrically bridged to the electronic component through the circuit structure.

60. The method for manufacturing the electronic package of claim 59, further comprising embedding a plurality of conductive pillars in the encapsulation layer, and the plurality of conductive pillars electrically connected to the circuit structure.

61. The method for manufacturing the electronic package of claim 59, further comprising forming a wiring structure on the second side of the interposer, and the wiring structure electrically connected to the conductors.

62. The method for manufacturing the electronic package of claim 61, further comprising forming a plurality of conductive components on the wiring structure.

63. A method for manufacturing an electronic package, comprising:
embedding the electronic component according to claim 6 served as an electrical bridging element in an encapsulation layer;
forming a circuit structure on the encapsulation layer, and the circuit structure electrically connected to the conductive protrusions of the electronic component; and
disposing a functional element on the circuit structure, the functional element electrically connected to the circuit structure, and the functional element electrically bridged to the electronic component through the circuit structure.

64. The method for manufacturing the electronic package of claim 63, further comprising embedding a plurality of conductive pillars in the encapsulation layer, and the plurality of conductive pillars electrically connected to the circuit structure.

65. The method for manufacturing the electronic package of claim 63, further comprising forming a wiring structure on the second side of the interposer, and the wiring structure electrically connected to the conductors.

66. The method for manufacturing the electronic package of claim 65, further comprising forming a plurality of conductive components on the wiring structure.

67. A method for manufacturing an electronic package, comprising:
embedding the electronic component according to claim 7 served as an electrical bridging element in an encapsulation layer;
forming a circuit structure on the encapsulation layer, and the circuit structure electrically connected to the conductive protrusions of the electronic component; and
disposing a functional element on the circuit structure, the functional element electrically connected to the circuit structure, and the functional element electrically bridged to the electronic component through the circuit structure.

68. The method for manufacturing the electronic package of claim 67, further comprising embedding a plurality of conductive pillars in the encapsulation layer, and the plurality of conductive pillars electrically connected to the circuit structure.

69. The method for manufacturing the electronic package of claim 67, further comprising forming a wiring structure on the second side of the interposer, and the wiring structure electrically connected to the conductors.

70. The method for manufacturing the electronic package of claim 69, further comprising forming a plurality of conductive components on the wiring structure.
